(19) United States
(12) Patent Application Publication
(10) Pub. No.: US 2016/0291377 A1
(43) Pub. Date: Oct. 6, 2016

(54) LIQUID CRYSTAL DISPLAY DEVICE

(71) Applicant: Japan Display Inc., Minato-ku (JP)

(72) Inventors: Masahiro KOSUGE, Minato-ku (JP); Toshimasa ISHIGAKI, Minato-ku (JP); Osamu ITOU, Minato-ku (JP)

(73) Assignee: Japan Display Inc., Minato-ku (JP)

(21) Appl. No.: 15/072,579

(22) Filed: Mar. 17, 2016

(30) Foreign Application Priority Data
Mar. 31, 2015 (JP) 2015-073176

(51) Int. Cl. G02F 1/1343; G02F 1/1333; G02F 1/1362; H01L 27/12; G02F 1/1368

(52) U.S. Cl. CPC G02F 1/13439; H01L 27/124; G02F 1/1368; G02F 1/136209; G02F 1/133345; G02F 2001/136222

(57) ABSTRACT

According to an aspect, a liquid crystal display device includes, in sequence, a thin-film transistor substrate comprising a thin-film transistor, a liquid crystal layer, and a counter substrate. The thin-film transistor substrate includes: a first translucent electrode; a color filter; metal wiring that is provided above the color filter and electrically coupled with the first translucent electrode; a light-absorbing layer provided on the metal wiring; and an optical interference layer provided on the light-absorbing layer. The optical interference layer includes the first translucent electrode.

### CROSS-REFERENCE TO RELATED APPLICATIONS

This application claims priority from Japanese Application No. 2015-073176, filed on Mar. 31, 2015, the contents of which are incorporated by reference herein in its entirety.

### BACKGROUND

1. Technical Field

The present disclosure relates to a liquid crystal display device that displays an image.

2. Description of the Related Art

Japanese Patent Application Laid-open Publication No. 2014-41268 discloses a liquid crystal display device having what is called a color-filter-on-array (COA) structure in which a color filter, pixel electrodes, and a common electrode are arranged on a thin-film transistor substrate on which thin-film transistors are provided. Japanese Patent Application Laid-open Publication No. 2012-185232 (JP-A-2012-185232) discloses a driving method for a liquid crystal display (LCD) device, such as an in-plane switching (IPS) method or a fringe field switching (FFS) method, in which pixel electrodes and a common electrode apply electric fields to a liquid crystal layer, the electric fields including an electric field parallel to a substrate plane.

A structure is known in which, in order to maintain a distance between a thin-film transistor substrate and a counter substrate with a liquid crystal layer interposed therebetween, spacers are provided on both the thin-film transistor substrate and the counter substrate, and the spacer on the thin-film transistor substrate side abuts on the spacer on the counter substrate side (refer to JP-A-2012-185232). In this case, disclination of the liquid crystal layer is liable to occur near the spacer on the counter substrate side. In view of this phenomenon, a light shielding layer is provided at a location overlapping the spacer on the counter substrate side to prevent an observer from viewing disturbances in a displayed image. When metal wiring containing a metal material such as aluminum is provided on the thin-film transistor substrate side on which pixel electrodes and a common electrode are arranged, the light shielding layer is provided on the counter substrate side to restrain reflected light from the metal wiring from being viewed. The light shielding layer needs to have an area equal to or larger than the area of the spacer and the area of the metal wiring, taking into account the bonding accuracy between the thin-film transistor substrate and the counter substrate. The increase in the area of the light shielding layer causes a reduction in the aperture ratio, and thus, may make it difficult to increase resolution of display images.

### SUMMARY

According to an aspect, a liquid crystal display device includes, in sequence, a thin-film transistor substrate comprising a thin-film transistor, a liquid crystal layer, and a counter substrate. The thin-film transistor substrate includes: a first translucent electrode; a color filter; metal wiring that is provided above the color filter and electrically coupled with the first translucent electrode; a light-absorbing layer provided on the metal wiring; and an optical interference layer provided on the light-absorbing layer. The optical interference layer includes the first translucent electrode.

### BRIEF DESCRIPTION OF THE DRAWINGS

FIG. 1 is a sectional view illustrating a schematic sectional structure of a liquid crystal display device according to a first embodiment;

FIG. 2 is a plan view of a pixel electrode according to the first embodiment;

FIG. 3 is a schematic sectional view of the liquid crystal display device taken along line III-III′ and viewed from the direction of the arrows in FIG. 2;

FIG. 4 is a schematic sectional view of a modification of the liquid crystal display device according to the first embodiment;

FIG. 5 is a plan view of a pixel electrode of a liquid crystal display device according to a second embodiment;

FIG. 6 is a schematic sectional view of the liquid crystal display device taken along line VI-VI′ and viewed from the direction of the arrows in FIG. 5;

FIG. 7 is a plan view of a pixel electrode of a liquid crystal display device according to a third embodiment;

FIG. 8 is a schematic sectional view of the liquid crystal display device taken along line VIII-VIII′ and viewed from the direction of the arrows in FIG. 7;

FIG. 9 is a plan view of a pixel electrode of a liquid crystal display device according to a fourth embodiment;

FIG. 10 is a schematic sectional view of the liquid crystal display device taken along line IX-IX′ and viewed from the direction of the arrows in FIG. 9;

FIG. 11 is a partial enlarged sectional view that is an enlarged view of metal wiring and an antireflection structure according to the fourth embodiment;

FIG. 12 is a plan view of a pixel electrode of a liquid crystal display device according to a fifth embodiment;

FIG. 13 is a schematic sectional view of the liquid crystal display device taken along line XIII-XIII′ and viewed from the direction of the arrows in FIG. 12;

FIG. 14 is a graph illustrating a relation between luminance Y of reflected light from metal wiring provided with an antireflection structure according to a first example and insulating layer film thickness;

FIG. 15 is a table illustrating an example of optimal film thickness of the antireflection structure;

FIG. 16 is a graph illustrating a distribution of chromaticity obtained by varying the thickness of the insulating layer;

FIG. 17 is a table illustrating values of the luminance Y obtained by varying the insulating layer film thickness and light-absorbing layer film thickness;

FIG. 18 is a table illustrating values of the chromaticity (x,y) obtained by varying the insulating layer film thickness and the light-absorbing layer film thickness;

FIG. 19 is a schematic sectional view of a liquid crystal display device according to a sixth embodiment;

FIG. 20 is a partial enlarged sectional view that is an enlarged view of the metal wiring and an antireflection structure according to the sixth embodiment;

FIG. 21 is a table illustrating values of the luminance Y obtained by varying common electrode film thickness and the light-absorbing layer film thickness according to a second example;

FIG. 22 is a table illustrating values of the chromaticity (x,y) obtained by varying the common electrode film thickness and the light-absorbing layer film thickness according to the second example;

FIG. 23 is a schematic sectional view of a liquid crystal display device according to a seventh embodiment;

FIG. 24 is a partial enlarged sectional view that is an enlarged view of the metal wiring and an antireflection structure according to the seventh embodiment;

FIG. 25 is a partial enlarged sectional view that is an enlarged view of the metal wiring and an antireflection structure according to a liquid crystal display device of an eighth embodiment;

FIG. 26 is a graph illustrating a relation between the luminance Y of reflected light from metal wiring provided with an antireflection structure according to a third example and the insulating layer film thickness;

FIG. 27 is a graph illustrating a distribution of the chromaticity obtained by varying the thickness of the insulating layer;

FIG. 28 is a table illustrating values of the luminance Y obtained by varying the insulating layer film thickness and the light-absorbing layer film thickness in the vicinity of a first local minimum value of the luminance Y;

FIG. 29 is a table illustrating values of the chromaticity (x,y) obtained by varying the insulating layer film thickness and the light-absorbing layer film thickness in the vicinity of the first local minimum value of the luminance Y;

FIG. 30 is a table illustrating values of the luminance Y obtained by varying the insulating layer film thickness and the light-absorbing layer film thickness in the vicinity of a second local minimum value of the luminance Y; and

FIG. 31 is a table illustrating values of the chromaticity (x,y) obtained by varying the insulating layer film thickness and the light-absorbing layer film thickness in the vicinity of the second local minimum value of the luminance Y.

### DETAILED DESCRIPTION

The following describes details of embodiments for carrying out the present invention with reference to the drawings. The present invention is not limited to the description of the embodiments to be given below. Components to be described below include a component or components that is/are easily conceivable by those skilled in the art or substantially the same component or components. The disclosure is merely an example, and the present invention naturally encompasses an appropriate modification maintaining the gist of the invention that is easily conceivable by those skilled in the art. To further clarify the description, a width, a thickness, a shape, and the like of each component may be schematically illustrated in the drawings as compared with an actual aspect. However, this is merely an example, and interpretation of the invention is not limited thereto. The same element as that described in the drawing that has already been discussed is denoted by the same reference numeral through the description and the drawings, and detailed description thereof will not be repeated in some cases where appropriate.

### First Embodiment

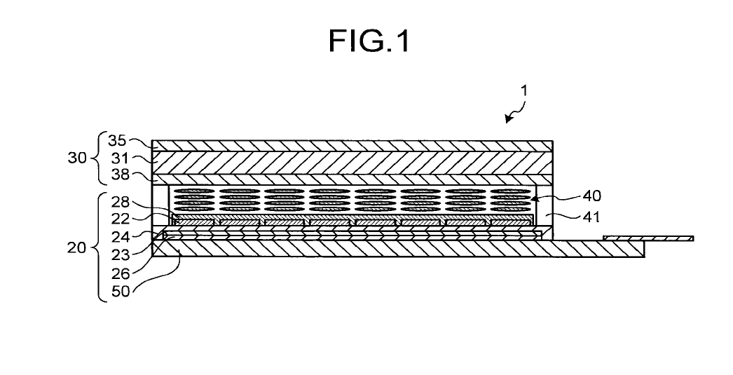

FIG. 1 is a sectional view illustrating a schematic sectional structure of a liquid crystal display device according to a first embodiment. As illustrated in FIG. 1, a liquid crystal display device 1 includes a thin-film transistor substrate 20, a counter substrate 30 facing the thin-film transistor substrate 20, and a liquid crystal layer 40 interposed between the thin-film transistor substrate 20 and the counter substrate 30.

The thin-film transistor substrate 20 includes a color filter 26 provided above a first substrate 50, a common electrode 23 serving as a first translucent electrode provided above the color filter 26, an insulating layer 24 provided on top of the common electrode 23, pixel electrodes 22 serving as second translucent electrodes provided on top of the insulating layer 24, and a first orientation film 28 provided on the top surface side of the thin-film transistor substrate 20. In the present specification, terms representing the upper direction (such as “over”, “above”, “top”, “upper”, and “upward”) refer to the direction from the thin-film transistor substrate 20 toward the counter substrate 30.

The counter substrate 30 includes a second substrate 31, a second orientation film 38 provided on the lower surface of the second substrate 31, and a polarizing plate 35 provided on the upper surface of the second substrate 31.

A sealing part 41 bonds the thin-film transistor substrate 20 to the counter substrate 30. The liquid crystal layer 40 is sealed in a space surrounded by the thin-film transistor substrate 20, the counter substrate 30, and the sealing part 41. The orientation direction of liquid crystal molecules of the liquid crystal layer 40 changes according to an electric field so as to control the amount of transmission of light. The liquid crystal display device 1 of the present embodiment is a liquid crystal display device of a transverse electric field mode, such as IPS mode and FFS mode, and liquid crystals suitable for such a liquid crystal display device are used for the liquid crystal layer 40.

In the liquid crystal display device 1 of the present embodiment, electric fields including an electric field parallel to an in-plane direction of the thin-film transistor substrate 20 are generated between the pixel electrodes 22 and the common electrode 23, and are applied to the liquid crystal layer 40. The applied electric field changes the direction of the liquid crystal molecules of the liquid crystal layer 40, and thus, performs switching between transmission and shielding of the incident light on the liquid crystal layer 40.

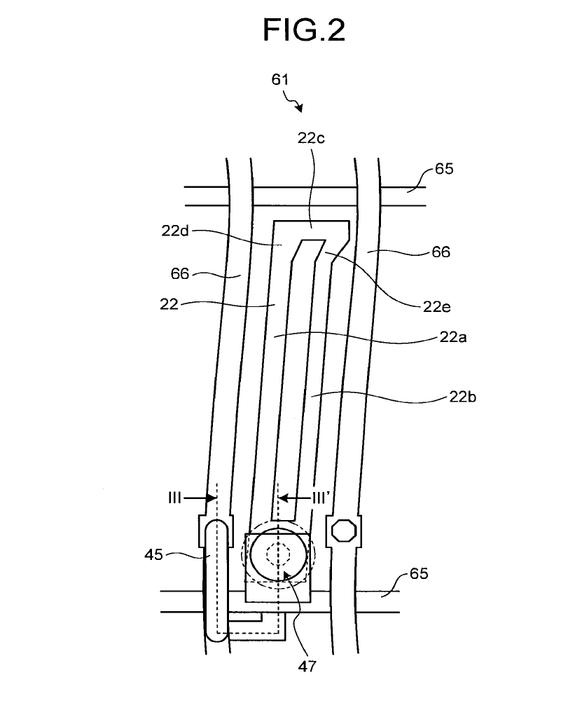

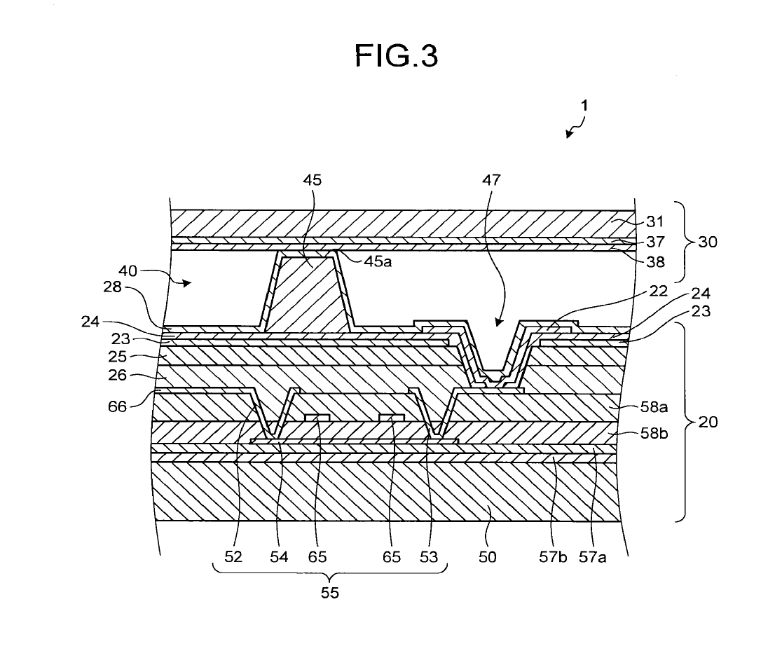

FIG. 2 is a plan view of one of the pixel electrodes according to the first embodiment. FIG. 3 is a schematic sectional view of the liquid crystal display device taken along line III-III′ and viewed from the direction of the arrows in FIG. 2. As illustrated in FIG. 3, the thin-film transistor substrate 20 in the liquid crystal display device 1 of the present embodiment includes a thin-film transistor 55, the pixel electrodes 22, the common electrode 23, and the color filter 26. In addition, the thin-film transistor substrate 20 includes a spacer 45 that projects upward and abuts on the counter substrate 30, and also includes the first orientation film 28 that is provided on at least part of the spacer 45 and has been photo-orientation-treated. The counter substrate 30 includes the second orientation film 38 facing the thin-film transistor substrate 20. The second orientation film 38 is provided on the second substrate 31 with a planarization layer 37 interposed therebetween.

In the present embodiment, the first orientation film 28 is a photo-orientation film, and the second orientation film 38 has been rubbing-orientation-treated. Anisotropy of the first orientation film 28 and the second orientation film 38 orients the liquid crystal molecules of the liquid crystal layer 40 in a certain direction.

The thin-film transistor substrate 20 is provided with the thin-film transistor 55 above the first substrate 50. The thin-film transistor 55 includes a semiconductor layer 54, a scanning line (gate electrode) 65, a source electrode 52, and a drain electrode 53. The first substrate 50 is a supporting substrate, such as a glass substrate and a silicon substrate. The first substrate 50 is provided with the semiconductor layer 54 with insulating layers 57a and 57b interposed therebetween. A semiconductor material, such as silicon, an oxide semiconductor, and a compound semiconductor, is used for the semiconductor layer 54. The source electrode 52 and the drain electrode 53 are coupled to the semiconductor layer 54 through contact holes of insulating layers 58a and 58b, and are coupled to a signal line 66 on the insulating layer 58a. The scanning line 65 is provided between the insulating layers 58a and 58b, and is isolated from the semiconductor layer 54. A metal material, such as aluminum and molybdenum, is used for the scanning line 65, the source electrode 52, and the drain electrode 53. A tetraethyl orthosilicate (TEOS) film or a plasma silicon nitride (PSiN) film, for example, is used for each of the insulating layers 57a, 57b, 58a, and 58b. In the present embodiment, the thin-film transistor 55 is, for example, an n-channel metal oxide semiconductor (MOS) thin-film transistor element.

As illustrated in FIG. 3, the color filter 26 is provided on top of the thin-film transistor 55. The liquid crystal display device 1 of the present embodiment is a liquid crystal display device having what is called a COA structure in which the color filter 26 is provided on the thin-film transistor substrate 20 side. A colored resin material is used for the color filter 26, in which filters colored, for example, in three colors of red (R), green (G), and blue (B) are cyclically arranged. One pixel serving as a unit of forming a color image contains, for example, a plurality of sub-pixels. One pixel contains a sub-pixel (R) for displaying red (R), a sub-pixel (B) for displaying blue (B), and a sub-pixel (G) for displaying green (G). The color filter 26 is colored corresponding to the respective sub-pixels (R), (G), and (B).

An overcoat layer 25 of, for example, a translucent resin is provided on top of the color filter 26. The common electrode 23, the insulating layer 24, and the pixel electrodes 22 are provided in this order on the overcoat layer 25. The common electrode 23 is continuously provided on top of the overcoat layer 25. The pixel electrodes 22 are provided in a layer different from the common electrode 23 with the insulating layer 24 interposed therebetween. As illustrated in FIG. 3, the overcoat layer 25 and the color filter 26 have a contact hole 47 penetrating upper and lower surfaces thereof. The pixel electrode 22 projects into the contact hole 47, and is electrically coupled to the drain electrode 53 provided at the bottom of the contact hole 47.

As illustrated in FIG. 2, the pixel electrode 22 is surrounded by the scanning lines 65 and 65 and the signal lines 66 and 66, and a region surrounded by the scanning lines 65 and 65 and the signal lines 66 and 66 serves as a sub-pixel 61. In the present embodiment, the sub-pixel 61 corresponds to any one of the sub-pixels (R), (G), and (B). The pixel electrodes 22 are arranged in a matrix in the plan view, and are plurally arranged along an extending direction of the scanning lines 65 and along an extending direction of the signal lines 66.

The pixel electrode 22 includes a plurality of electrode branches 22a and 22b extending in a direction along the signal lines 66, and includes, at ends of the electrode branches 22a and 22b, bent portions 22d and 22e bent from extending directions of the electrode branches 22a and 22b, respectively. A connecting portion 22c connects the end of the bent portion 22d to the end of the bent portion 22e.

As illustrated in FIG. 2, the scanning lines 65 for transmitting driving signals to the thin-film transistor 55 extend. A driving voltage transmitted through the scanning line 65 can switch the on and off operations of the thin-film transistor 55 illustrated in FIG. 3. The signal lines 66 for transmitting image signals to the pixel electrodes 22 extend in a direction intersecting the scanning lines 65. The signal lines 66 extend as a whole in a direction orthogonal to the scanning lines 65 in the plan view, but may be inclined on a pixel-by-pixel basis. Each of the signal lines 66 is coupled to the source electrode 52 illustrated in FIG. 3, and each of the image signals is transmitted to the corresponding pixel electrode 22 when the thin-film transistor 55 is on.

As illustrated in FIG. 3, the spacer 45 projects from the upper side of the insulating layer 24 toward the counter substrate 30. The spacer 45 is trapezoidal in a sectional view, having sloped side surfaces and having an upper end 45a with an area smaller than an area on the lower end side. As illustrated in FIG. 2, the spacer 45 is arranged along the signal line 66 in the plan view. The spacer 45 is formed of a translucent resin such as an acrylic resin by, for example, a photolithography process. The shape of the spacer 45 is not limited to the shape described above. The spacer 45 may be, for example, circular in the plan view, and a plurality of the spacers 45 may be arranged between two scanning lines 65 continually along the signal lines 66.

The first orientation film 28 is provided on or above the pixel electrode 22 and the insulating layer 24, and is also provided on the upper end 45a and the side surfaces of the spacer 45. In the present embodiment, the first orientation film 28 is a photodegradation-type photo-orientation film, for which a photoreactive material is used. The first orientation film 28 is made of a polyamic-acid-ester-based material illustrated in, for example, Japanese Patent Application Laid-open Publication No. 2005-351924 and Japanese Patent Application Laid-open Publication No. 2009-75569. The first orientation film 28 is subjected to the photo-orientation treatment in which the orientation film is irradiated with ultraviolet rays in a certain direction. This treatment photodegrades a cyclobutane skeleton in a polyimide main chain oriented in a polarization direction, so that the polyimide chain is cur off.

As illustrated in FIG. 3, the second substrate 31 has a flat surface facing the thin-film transistor substrate 20. The second orientation film 38 is provided on the flat surface of the second substrate 31 with the planarization layer 37 interposed therebetween. A glass substrate or a sheet-like base material containing a translucent resin material can be used for the second substrate 31. The second orientation film 38 has a flat surface facing the thin-film transistor substrate 20 over the entire surface in the pixel. In the present embodiment, this configuration allows the rubbing orientation treatment to be easily performed using a roller or the like to provide the anisotropy to the second orientation film 38.

As illustrated in FIG. 3, the first orientation film 28 provided on the upper end 45a of the spacer 45 abuts on the flat surface of the second orientation film 38 of the counter substrate 30. This configuration causes the spacer 45 to maintain a distance between the thin-film transistor substrate 20 and the counter substrate 30.

The liquid crystal display device 1 of the present embodiment includes the thin-film transistor substrate 20 including the thin-film transistor 55, the pixel electrodes 22, the common electrode 23, and the color filter 26, and also includes the counter substrate 30 facing the thin-film transistor substrate 20 with the liquid crystal layer 40 interposed therebetween. The thin-film transistor substrate 20 includes the spacer 45 that projects upward and maintains the distance between the thin-film transistor substrate 20 and the counter substrate 30, and also includes the first orientation film 28 that is provided on top of or above the pixel electrode 22 or the common electrode 23 and on at least part of the spacer 45. The counter substrate 30 includes the second orientation film 38 that is provided to the surface of the second substrate 31, and that has been rubbing-orientation-treated, the surface facing the thin-film transistor substrate 20.

That is to say, the liquid crystal display device 1 of the present embodiment has a COA structure in which the color filter 26 is provided to the thin-film transistor substrate 20, and the spacer 45 is provided only to the thin-film transistor substrate 20. The counter substrate 30 is provided with no spacers, and the second substrate 31 has the flat surface facing the thin-film transistor substrate 20. The second orientation film 38 has the flat surface facing the thin-film transistor substrate 20 over the entire surface in the pixel. This configuration makes the rubbing orientation treatment for the second orientation film 38 easy. Applying the photo-orientation treatment to the orientation film causes the photodegradation reaction to cut off the polyimide chain, so that the strength decreases. Thus, by using a film having been rubbing-orientation-treated as the second orientation film 38, the strength of the second orientation film 38 is maintained, so that the second orientation film 38 is restrained from peeling when abutting on the upper end 45a of the spacer 45.

The second orientation film 38 having been rubbing-orientation-treated controls the orientation of the liquid crystal layer 40 near places where the first orientation film 28 provided on the upper end 45a of the spacer 45 abuts on the second orientation film 38, so that the disclination is restrained from occurring on the counter substrate 30 side of the liquid crystal layer 40. The first orientation film 28 is provided on at least the side surfaces of the spacer 45, so that the disclination is also restrained from occurring on the thin-film transistor substrate 20 side of the liquid crystal layer 40.

The spacer 45 is arranged along the signal line 66, so that the spacer 45 can be provided while maintaining distances between a plurality of sub-pixels arranged adjacent to each other, and hence, can be used for a high-resolution liquid crystal display device.

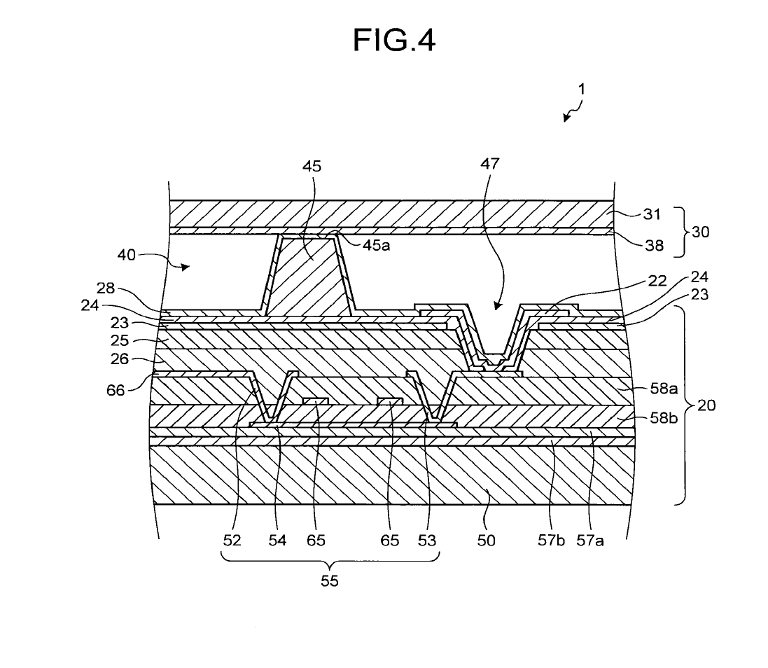

FIG. 4 is a schematic sectional view of a first modification of the liquid crystal display device according to the first embodiment. This liquid crystal display device 1 of the modification illustrated in FIG. 4 differs from that of the above-described embodiment in the following point: in the counter substrate 30, no planarization layer is interposed between the second substrate 31 and the second orientation film 38, so that the second orientation film 38 is in contact with the second substrate 31. Thus, the configuration in which the second orientation film 38 is in contact with the second substrate 31 simplifies the production process of the counter substrate 30 and reduces the production cost thereof. In addition, the reduction of the members on the display surface side of the liquid crystal display device 1 increases the light transmittance.

### Second Embodiment

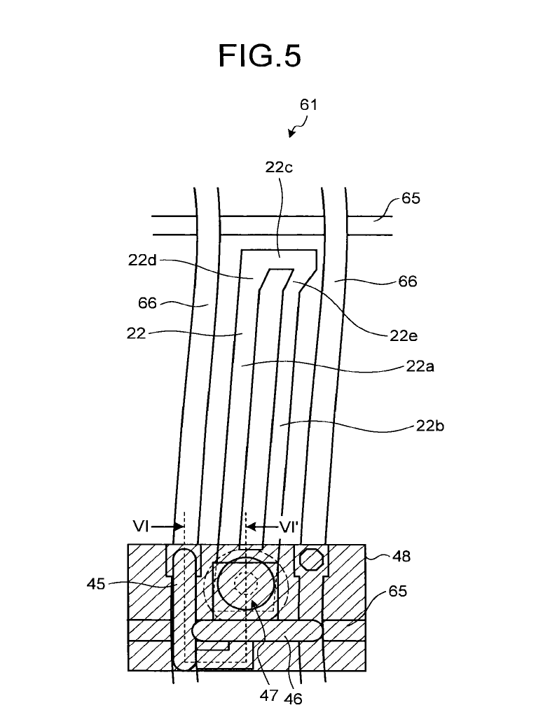

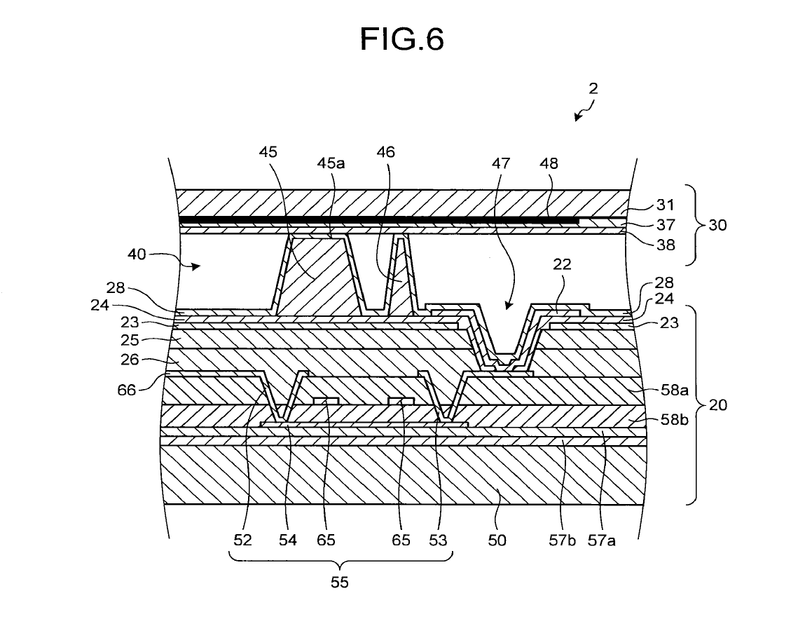

FIG. 5 is a plan view of a pixel electrode of a liquid crystal display device according to a second embodiment. FIG. 6 is a schematic sectional view of the liquid crystal display device taken along line VI-VI′ and viewed from the direction of the arrows in FIG. 5. As illustrated in FIG. 5, for example, the pixel electrodes 22, the scanning lines 65, the signal lines 66 of the present embodiment are the same as those of the first embodiment. The difference is that the liquid crystal display device of the present embodiment includes not only the spacer 45 but also a spacer 46. The spacer 45 is arranged along the signal line 66 in the plan view, and extends in the extending direction of the signal line 66. The spacer 46 is arranged along the scanning line 65 in the plan view, and extends in the extending direction of the scanning line 65.

Both the spacer 45 and the spacer 46 are provided to the thin-film transistor substrate 20, and project upward from the insulating layer 24 for insulation between layers of the pixel electrode 22 and the common electrode 23 so as to abut on the second orientation film 38. Also in the present embodiment, the second orientation film 38 has been rubbing-orientation-treated, and thus has a higher mechanical strength than an orientation film having been photo-orientation-treated. As a result, the second orientation film 38 is prevented, for example, from peeling even when the spacers 45 and 46 are provided.

In this liquid crystal display device 2 of the present embodiment, the counter substrate 30 includes a shielding layer 48 in a region near the contact hole 47. As illustrated in FIG. 6, the shielding layer 48 is provided under the second substrate 31, and the planarization layer 37 and the second orientation film 38 are provided under the shielding layer 48. As illustrated in FIG. 5, the shielding layer 48 is arranged so as to overlap the contact hole 47, the spacer 45, and the spacer 46, in the plan view. The shielding layer 48 extends in the extending direction of the scanning line 65, and has a width equal to or larger than the length of the spacer 45 in the extending direction of the signal line 66.

### Third Embodiment

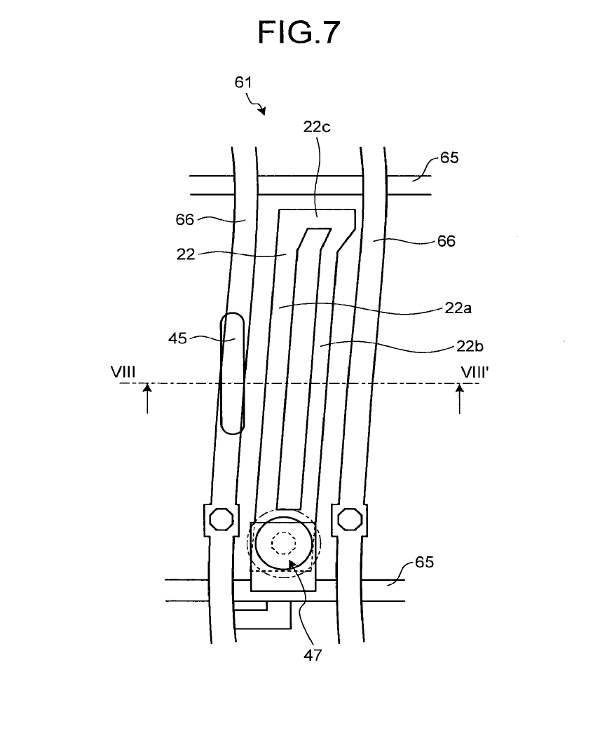

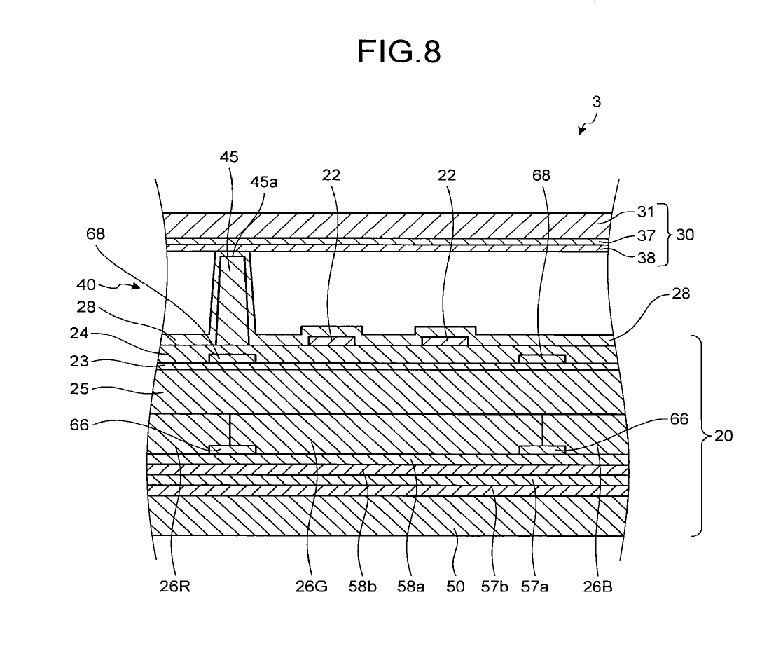

FIG. 7 is a plan view of a pixel electrode of a liquid crystal display device according to a third embodiment. FIG. 8 is a schematic sectional view of the liquid crystal display device taken along line VIII-VIII′ and viewed from the direction of the arrows in FIG. 7. As illustrated in FIG. 7, the spacer 45 is arranged along the signal line 66 in the plan view, and is located between two scanning lines 65 and 65 on both sides of the pixel electrode 22.

As illustrated in FIG. 8, the color filter 26 includes a color filter 26R corresponding to the sub-pixel (R), a color filter 26B corresponding to the sub-pixel (B), and a color filter 26G corresponding to the sub-pixel (G). The color filters 26R, 26G, and 26B are arranged in a cyclically repeating manner. The sub-pixel 61 of the present embodiment corresponds to, for example, one sub-pixel (G). The signal lines 66 are arranged at locations overlapping the boundaries between the color filters 26R, 26G, and 26B. The spacer 45 is arranged at a location overlapping the boundary between the color filters 26R and 26G.

In this liquid crystal display device 3 of the present embodiment, metal wiring 68 (not illustrated in FIG. 7) is provided on top of the common electrode 23. The metal wiring 68 is arranged at locations overlapping the signal lines 66, and extends in the same direction as that of the signal lines 66 while having a width equal to or slightly larger than that of the signal lines 66. The metal wiring 68 is provided along the boundaries between the color filters 26R, 26G, and 26B continuously across a plurality of sub-pixels. The spacer 45 is arranged above the metal wiring 68. The metal wiring 68 is made of a metal material, such as aluminum, copper, and nickel, or made of an alloy material of these elements, and has electrical conductivity higher than that of the common electrode 23. The metal wiring 68 is provided on top of the common electrode 23, so that the total resistance value of the common electrode 23 and the metal wiring 68 is lower than the resistance value of the common electrode 23 alone. This lower resistance prevents, for example, delay and crosstalk of signals from occurring.

### Fourth Embodiment

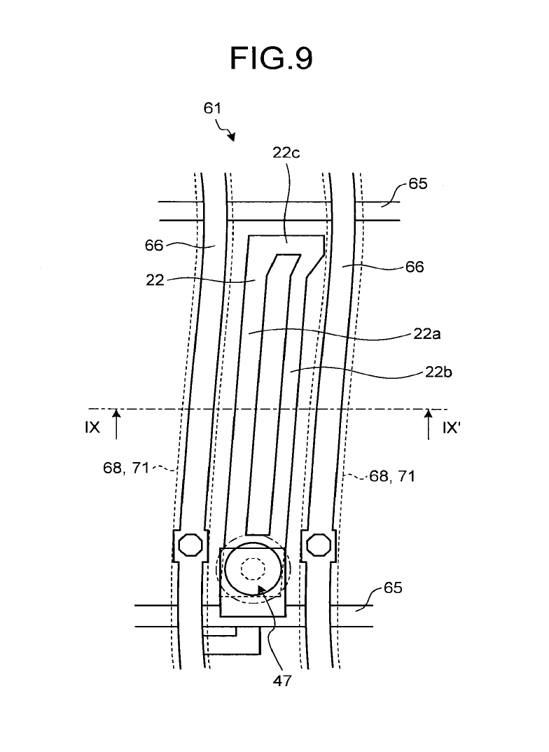

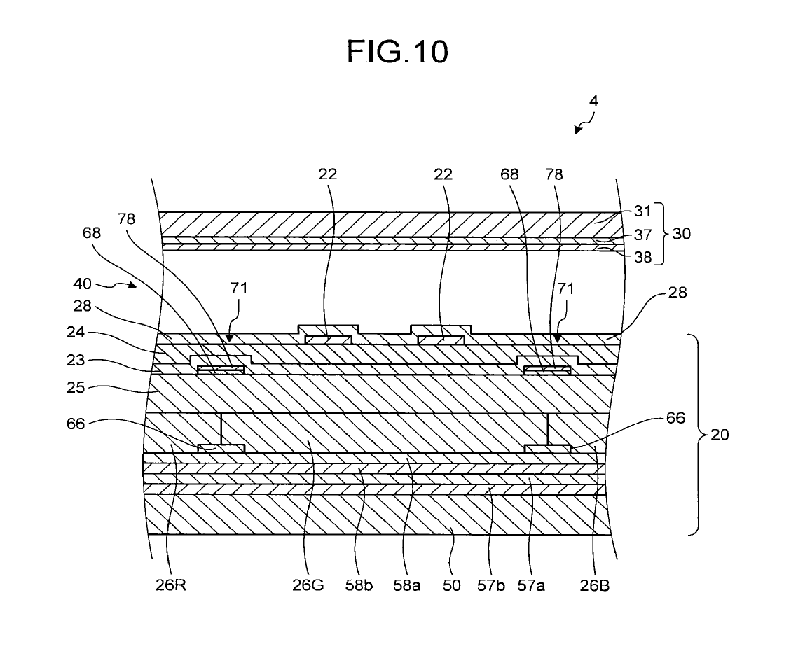

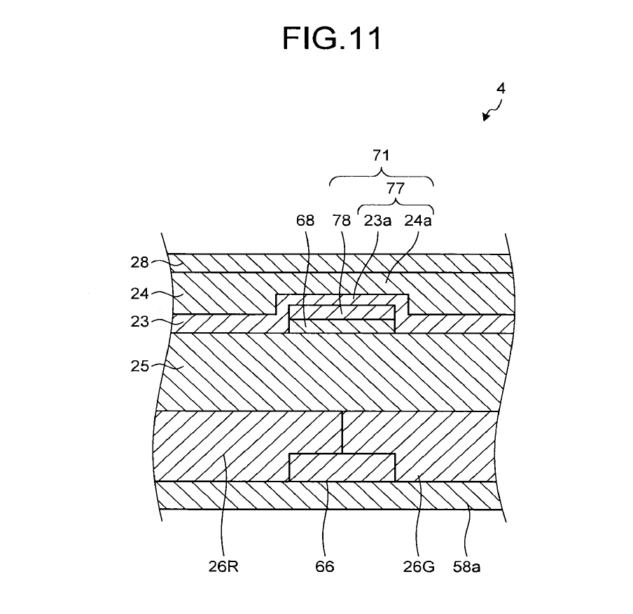

FIG. 9 is a plan view of a pixel electrode of a liquid crystal display device according to a fourth embodiment. FIG. 10 is a schematic sectional view of the liquid crystal display device taken along line IX-IX′ and viewed from the direction of the arrows in FIG. 9. FIG. 11 is a partial enlarged sectional view that is an enlarged view of the metal wiring and an antireflection structure. This liquid crystal display device 4 of the present embodiment includes the metal wiring 68 that is provided above the thin-film transistor 55 and is in contact with the common electrode 23, and also includes an antireflection structure 71 provided on top of the metal wiring 68.

The metal wiring 68 is provided on top of the overcoat layer 25. The metal wiring 68 and the antireflection structure 71 are arranged above the signal line 66. The metal wiring 68 and the antireflection structure 71 extend in the same direction along the signal lines 66 and 66, and are provided along the boundaries between the color filters 26R, 26G, and 26B.

As illustrated in FIG. 11, the antireflection structure 71 includes a light-absorbing layer 78 for reducing reflected light from the metal wiring 68 and an optical interference layer 77 provided on top of the light-absorbing layer 78. The light-absorbing layer 78 has a function to absorb incident light. The incident light from above and the reflected light from the metal wiring 68 are attenuated while passing through the light-absorbing layer 78. This attenuation restrains the reflected light from the metal wiring 68 from being viewed by an observer. The light-absorbing layer 78 is made of, for example, Al—X—N (where X is, for example, Cu, Mo, Ni, or Cr). The material used for the light-absorbing layer 78 is not limited to this material. When a complex refractive index N of the light-absorbing layer 78 is represented by N=n−ik, the material preferably has an absorption coefficient k of 2 or larger in the visible light region (380 nm to 780 nm). The incident light on the light-absorbing layer 78 is more attenuated as the absorption coefficient k increases. The absorption coefficient k changes with the wavelength of light. Accordingly, the light-absorbing layer 78 may be changed in composition and/or film thickness according to the wavelength of the incident light. In the present embodiment, the thickness of the light-absorbing layer 78 is, for example, 30 nm to 60 nm.

In the present embodiment, the optical interference layer 77 includes the common electrode 23 and the insulating layer 24 provided on top of the common electrode 23. The optical interference layer 77 causes the phase of the reflected light from the upper surface of the metal wiring 68 to be opposite to the phase of the reflected light from the upper surface of the optical interference layer 77 so that the two beams of reflected light will cancel each other out. This canceling out restrains the reflected light from the metal wiring 68 from being viewed by the observer.

In the present embodiment, the common electrode 23 is continuously provided on the upper surface of the overcoat layer 25, the side surfaces of the metal wiring 68, and the side surfaces and the upper surface of the light-absorbing layer 78, and includes an overlapping portion 23a overlapping the metal wiring 68, the overlapping portion 23a being included in the antireflection structure 71. This configuration allows the antireflection structure 71 to be provided using a reduced number of optical functional layers, and can restrain the production cost from increasing.

The lower surface of the common electrode 23 is raised upward on top of the metal wiring 68 and the light-absorbing layer 78 so as to have a recessed shape. As a result, the common electrode 23 can be easily provided on top of the metal wiring 68 and the light-absorbing layer 78 even when the upper surface of the overcoat layer 25 is flat. In addition, the upper surface of the common electrode 23 projects upward on the upper side of the metal wiring 68 and the light-absorbing layer 78 so as to have a projecting shape. As a result, the overlapping portion 23a of the common electrode 23 overlapping the metal wiring 68 can have the same thickness as that of the other portions. The overlapping portion 23a may have a thickness different from those of the portions of the common electrode 23 other than the overlapping portion 23a.

For example, a translucent conductive material, such as indium tin oxide (ITO) and ZnO, is used for the common electrode 23. The translucent conductive material, such as ITO and ZnO, has a refractive index n of 1.7 to 2.0 and an absorption coefficient k of 0, in the visible light region, so that the common electrode 23 has a function as an optical interference layer.

In the present embodiment, in order to restrain the resistance value of the common electrode 23 from increasing and to appropriately transmit light, the common electrode 23 has a film thickness of, for example, 20 nm to 150 nm. When the film thickness is in the range described above, the reflection of visible light is effectively interfered and the reflection can be prevented.

As illustrated in FIGS. 10 and 11, the insulating layer 24 for insulation between layers of the pixel electrode 22 and the common electrode 23 is provided on the upper surface of the common electrode 23, and includes an overlapping portion 24a overlapping the metal wiring 68 in the plan view, the overlapping portion 24a being included in the antireflection structure 71.

An insulating material such as silicon nitride (SiN) is used for the insulating layer 24. SiN has a refractive index n of 2.0 to 2.1 and an absorption coefficient k of 0, in the visible light region. In the present embodiment, in order to appropriately ensure the interlayer insulation between the pixel electrode 22 and the common electrode 23 and to appropriately transmit light, the insulating layer 24 has a film thickness of, for example, 40 nm to 250 nm.

In the liquid crystal display device 4 of the present embodiment, the side surfaces of the metal wiring 68 are in contact with the common electrode 23, as illustrated in FIG. 11. This configuration conducts electricity between the metal wiring 68 and the common electrode 23 to reduce the resistance value of the common electrode 23.

The side surfaces of the metal wiring 68 and the light-absorbing layer 78 are orthogonal to the upper surface of the overcoat layer 25. However, the side surfaces of the metal wiring 68 or the light-absorbing layer 78 may be inclined to have a tapered shape.

### Fifth Embodiment

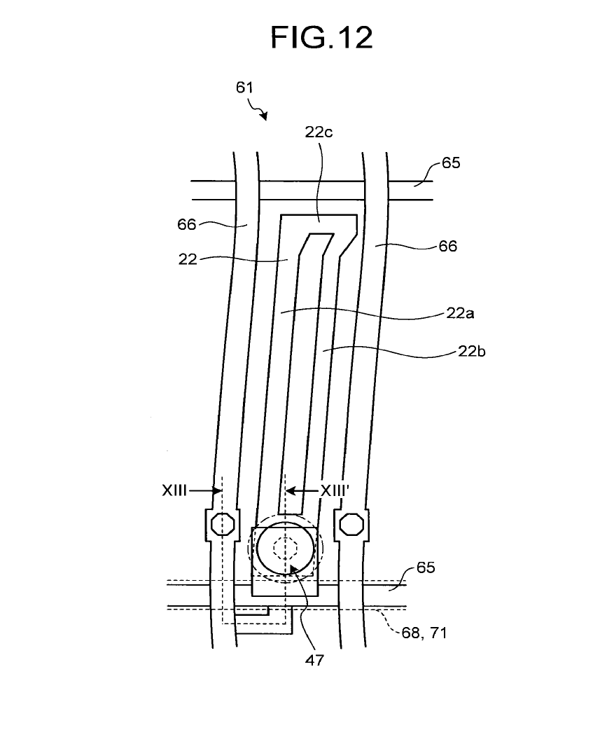

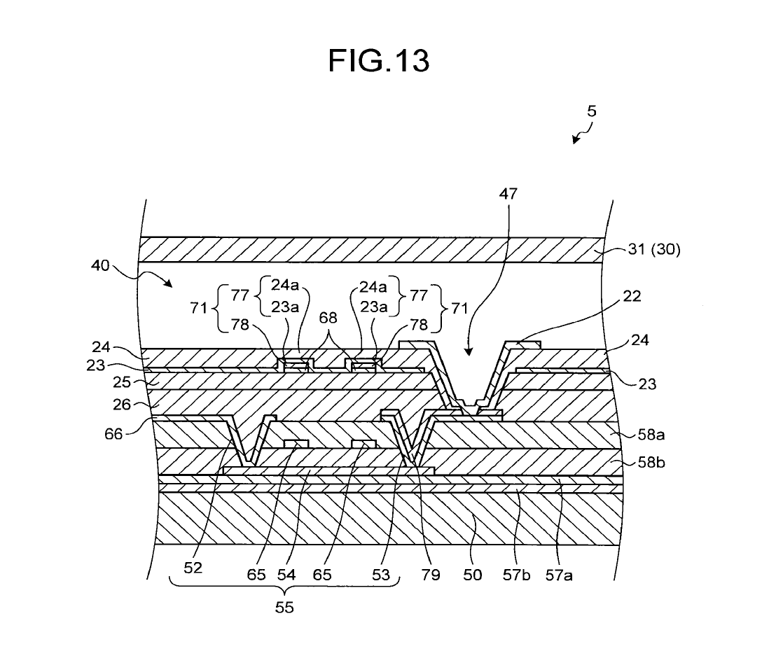

FIG. 12 is a plan view of a pixel electrode of a liquid crystal display device according to a fifth embodiment. FIG. 13 is a schematic sectional view of the liquid crystal display device taken along line XIII-XIII′ and viewed from the direction of the arrows in FIG. 12. As illustrated in FIG. 12, the metal wiring 68 and the antireflection structure 71 are provided along the scanning line 65. As illustrated in FIG. 13, the antireflection structure 71 including the optical interference layer 77 and the light-absorbing layer 78 is provided above or on the scanning line 65 and the metal wiring 68. The antireflection structure 71 of the present embodiment has the same configuration as that of the antireflection structure 71 illustrated in the fourth embodiment. In this manner, this liquid crystal display device 5 can appropriately prevent the reflection from the metal wiring 68 provided above the scanning lines 65. The metal wiring 68 and the antireflection structure 71 may be provided above the scanning lines 65 and the signal lines 66.

As illustrated on FIG. 13, a light-absorbing layer 79 is provided on top of the drain electrode 53. The light-absorbing layer 79 is made of Al—X—N(where X is, for example, Cu, Mo, Ni, or Cr). The light-absorbing layer 79 is partially opened in the contact hole 47, so that the drain electrode 53 is exposed through the light-absorbing layer 79. The exposed drain electrode 53 is coupled to the pixel electrode 22. The light-absorbing layer 79 is provided on top of the drain electrode 53, so that reflected light from the drain electrode 53 in the contact hole 47 is restrained from being viewed by the observer. As illustrated on FIG. 13, the antireflection structure 71 including the optical interference layer 77 and the light-absorbing layer 78 is provided above the scanning line 65.

### First Example

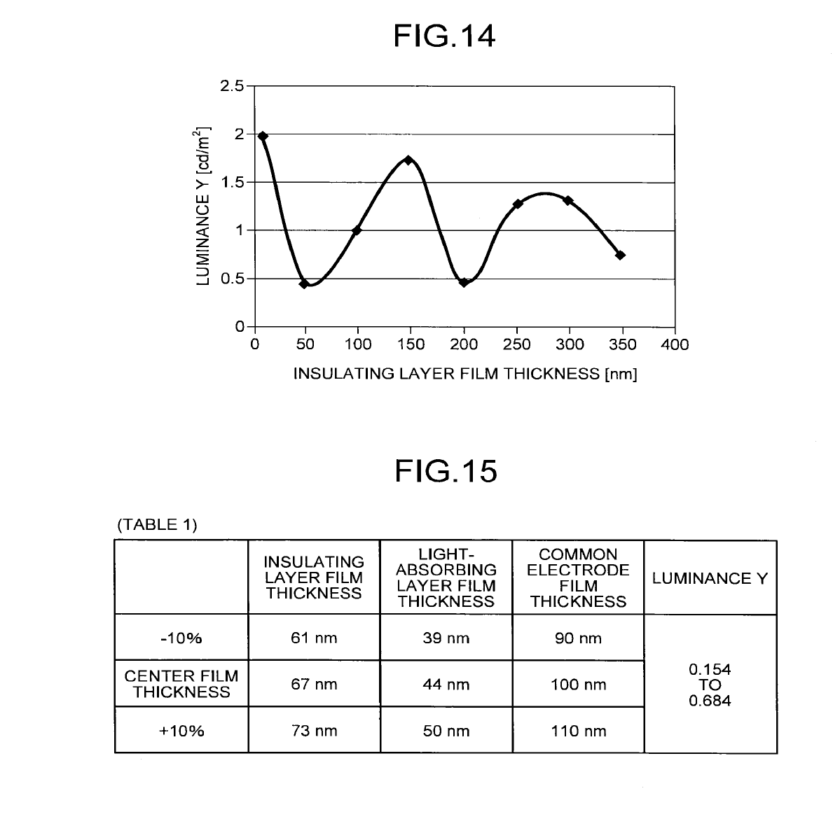

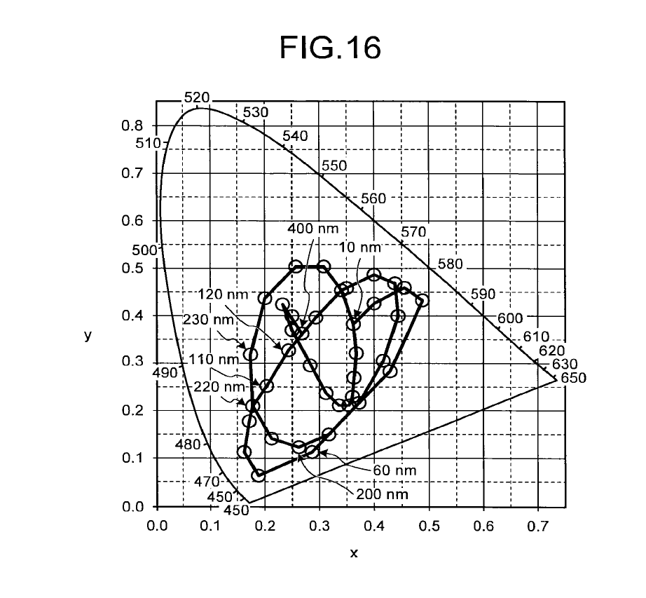

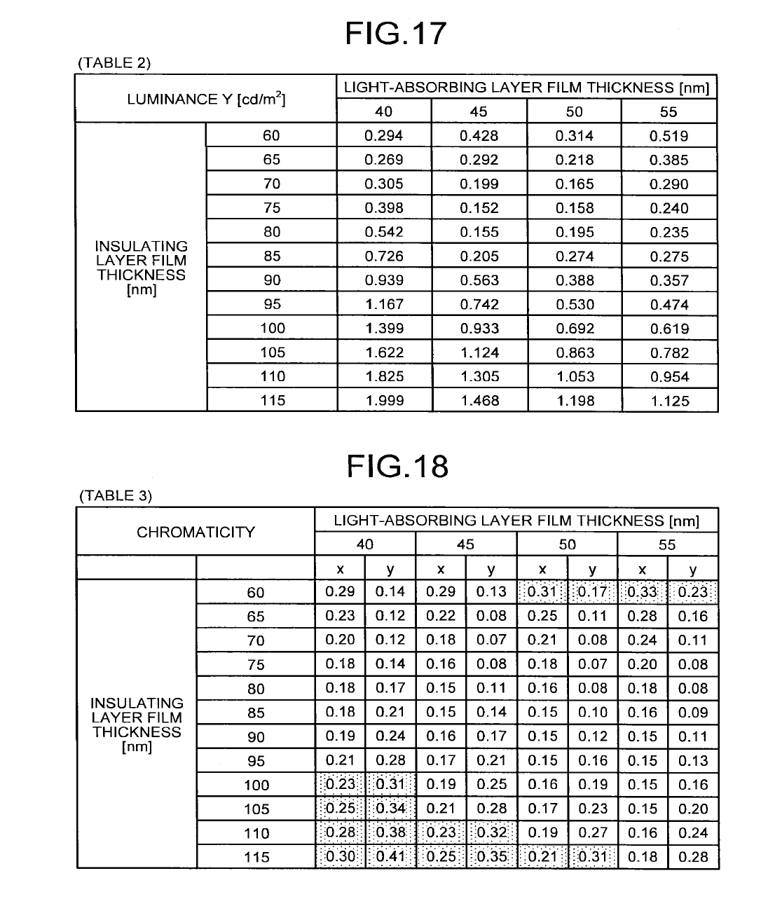

FIG. 14 is a graph illustrating a relation between luminance Y of reflected light from metal wiring provided with an antireflection structure according to a first example and insulating layer film thickness. FIG. 15 is a table illustrating an example of optimal film thickness of the antireflection structure according to the first example. FIG. 16 is a graph illustrating a distribution of chromaticity obtained by varying the thickness of the insulating layer. FIG. 17 is a table illustrating values of the luminance Y obtained by varying the insulating layer film thickness and light-absorbing layer film thickness. FIG. 18 is a table illustrating values of the chromaticity (x,y) obtained by varying the insulating layer film thickness and the light-absorbing layer film thickness.

A liquid crystal display device according to the present example has the same configuration as that of the liquid crystal display device 4 of the fourth embodiment illustrated in FIG. 11. In the present example, the light-absorbing layer 78 is made of Al—Cu—N, and the common electrode 23 is made of ITO. The film thicknesses of the light-absorbing layer 78, the common electrode 23, and the insulating layer 24 were varied, and the luminance Y and the chromaticity of the reflected light were evaluated. Then, the film thicknesses of the respective layers of the antireflection structure 71 were optimized. A D65 light source serving as a standard light source was used as a light source. In this measurement, the D65 light source emitted light of a constant intensity from a constant distance. When the D65 light source emitted the light to the metal wiring 68 that is provided with neither the optical interference layer 77 nor the light-absorbing layer 78 as an upper layer, the metal wiring 68 reflected the light at a luminance of about 5 cd/m².

The graph of FIG. 14 illustrates the relation between the film thickness of the insulating layer 24 and the luminance Y when the film thickness of the light-absorbing layer 78 is 44 nm and the film thickness of the common electrode 23 is 100 nm. In the range that the film thickness of the insulating layer 24 is 10 nm to 350 nm, the luminance Y has two local minima at points where the film thickness of the insulating layer 24 is about 60 nm and about 200 nm. When manufacturing errors are taken into account, the film thickness of the antireflection structure 71 for reducing the luminance Y of the reflected light is preferably such that the insulating layer 24 has a film thickness of 61 nm to 73 nm (center film thickness of 67 nm), as illustrated in TABLE 1 of FIG. 15.

The following describes the film thicknesses of the antireflection structure 71 when a restriction in the chromaticity is taken into account. FIG. 16 is an xy chromaticity diagram based on the CIE-XYZ color system, and is called a CIE system or a CIR chromaticity diagram. Y among tristimulus values X, Y, and Z is used as a value for representing the luminance. The xy chromaticity diagram is an international representation system created by the International Commission on Illumination (CIE). The points in FIG. 16 represent the respective chromaticities obtained by setting the film thickness of the light-absorbing layer 78 to 44 nm and the film thickness of the common electrode 23 to 100 nm, and varying the thickness of the insulating layer 24 at intervals of 10 nm in the range of 100 nm to 400 nm. Here, the following relations hold: x=X/(X+Y+Z) and y=Y/(X+Y+Z).

To increase the resolution of the liquid crystal display device, it is important to make it difficult for human eyes to view the reflected light from the metal wiring 68. For that purpose, the luminance of the reflected light is preferably reduced first by the antireflection structure 71. It is known that, if the luminance is the same, the reflected light is more difficult to be viewed when the values of x and y of the chromaticity (x,y) are smaller, and is particularly difficult to be viewed when x≦0.3 and y≦0.3. Accordingly, the reflected light is preferably controlled by the antireflection structure 71 so as to reduce the values of x and y in the chromaticity of the reflected light.

FIG. 16 indicates the following. If the film thickness of the light-absorbing layer 78 is 44 nm and the film thickness of the common electrode 23 is 100 nm, the chromaticity satisfies x≦0.3 and y≦0.3 when the film thickness of the insulating layer 24 is in the range of 60 nm to 115 nm and in the range of 193 nm to 228 nm.

As illustrated in FIGS. 14 and 15, the luminance Y is minimized when the film thickness of the optical interference layer 77 is about 167 nm. TABLE 2 of FIG. 17 illustrates values of the luminance Y when the film thickness of the common electrode 23 is fixed to 100 nm. As illustrated in FIG. 17, when the film thickness of the light-absorbing layer 78 is 45 nm, the luminance Y is smaller in the range of the insulating layer 24 of 60 nm to 90 nm.

TABLE 3 of FIG. 18 illustrates values of the chromaticity when the film thickness of the common electrode 23 is fixed to 100 nm. The chromaticity (x,y) satisfies x≦0.3 and y≦0.3 when the film thickness of the insulating layer 24 is in the range of 65 nm to 95 nm, where the center film thickness is 80 nm. Accordingly, when the chromaticity (of x≦0.3 and y≦0.3), the luminance Y, and the manufacturing errors are taken into account, the film thickness of the antireflection structure 71 is preferably such that the insulating layer 24 has a film thickness of 72 nm to 88 nm (center film thickness of 80 nm), the common electrode 23 has a film thickness of 90 nm to 110 nm (center film thickness of 100 nm), and the light-absorbing layer 78 has a film thickness of 45 nm to 55 nm (center film thickness of 50 nm).

### Sixth Embodiment

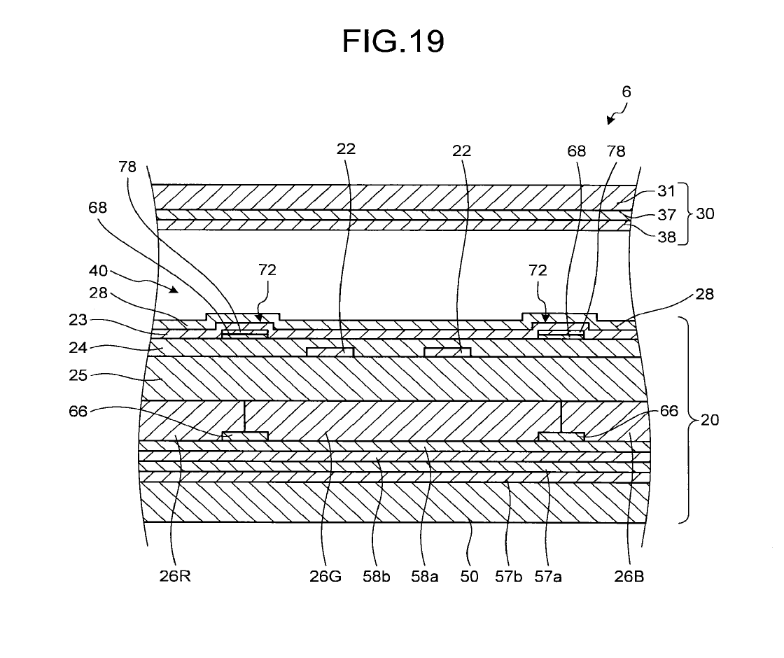

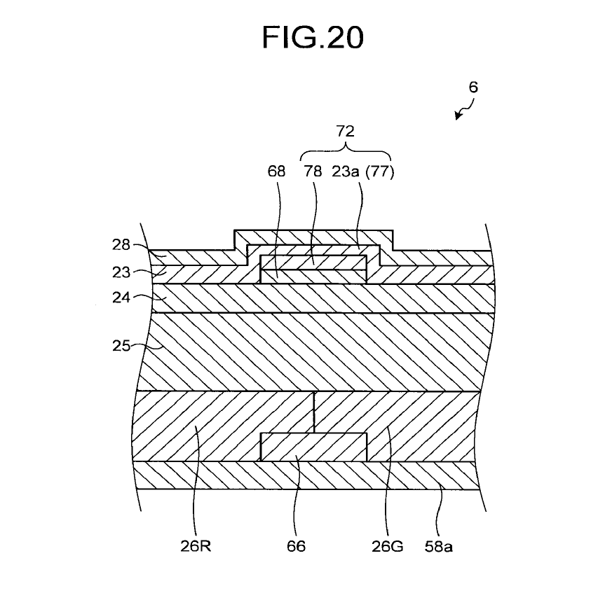

FIG. 19 is a schematic sectional view of a liquid crystal display device according to a sixth embodiment. FIG. 20 is a partial enlarged sectional view that is an enlarged view of the metal wiring and an antireflection structure according to the sixth embodiment. This liquid crystal display device 6 of the present embodiment differs from those of the above-described embodiments in the order of stacking the pixel electrode 22 and the common electrode 23. As illustrated in FIG. 19, the pixel electrode 22 is provided on top of the overcoat layer 25. The insulating layer 24 is provided on top of the pixel electrode 22 and the overcoat layer 25. The metal wiring 68 is provided on top of the insulating layer 24, and the common electrode 23 is continuously provided on top of the metal wiring 68 and the insulating layer 24.

As illustrated in FIG. 20, an antireflection structure 72 is provided on top of the metal wiring 68. The antireflection structure 72 includes the light-absorbing layer 78 for reducing the reflected light from the metal wiring 68 and the optical interference layer 77 provided on top of the light-absorbing layer 78.

The thickness of the light-absorbing layer 78 is, for example, 30 nm to 60 nm. The film thickness of the common electrode 23 is, for example, 20 nm to 150 nm.

As described above, the liquid crystal display device 6 of the present embodiment includes the antireflection structure 72 in which the light-absorbing layer 78 and the optical interference layer 77 are provided in this order on top of the metal wiring 68. In the present embodiment, unlike in the fourth embodiment, the insulating layer 24 is located under the metal wiring 68, and hence, does not contribute to the interference of the light above the metal wiring 68. Also in such an aspect, the antireflection structure 72 restrains the reflected light from the metal wiring 68 from being viewed by the observer.

### Second Example

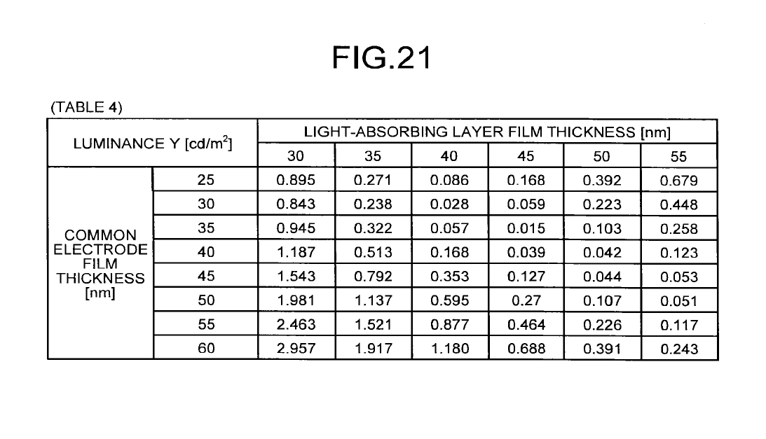

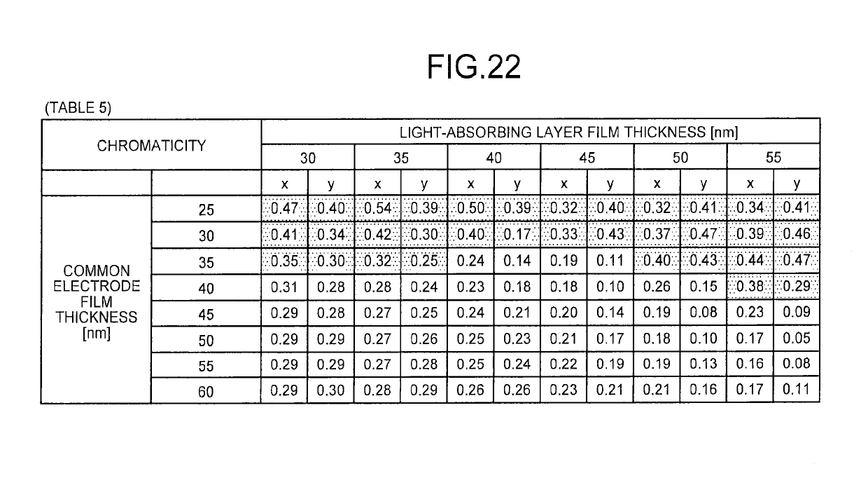

FIG. 21 is a table illustrating the values of the luminance Y obtained by varying the common electrode film thickness and the light-absorbing layer film thickness according to a second example. FIG. 22 is a table illustrating the values of the chromaticity (x,y) obtained by varying the common electrode film thickness and the light-absorbing layer film thickness according to the second example. The liquid crystal display device 6 of the sixth embodiment serves as a liquid crystal display device according to the second example.

According to TABLE 4 of FIG. 21, from the viewpoint of the luminance Y, the film thickness ranges are preferably such that the light-absorbing layer 78 has a film thickness of 40 nm to 50 nm (center film thickness of 45 nm), and the common electrode 23 has a film thickness of 30 nm to 40 nm (center film thickness of 35 nm).

As illustrated in TABLE 5 of FIG. 5, the film thickness ranges in which the chromaticity (x,y) satisfies x≦0.3 and y≦0.3 are preferably such that the common electrode 23 has a film thickness of 45 nm or larger when the chromaticity (x,y) is taken into account, and has a film thickness of 45 nm to 55 nm (center film thickness of 50 nm) when manufacturing errors are taken into account.

The results described above indicate that the reflected light is also reduced when the common electrode 23 is provided on top of the metal wiring 68 and the insulating layer 24 is placed under the metal wiring 68, as illustrated in FIGS. 19 and 20. As a result, no shielding layer needs to be provided to the counter substrate 30 at locations overlapping the metal wiring 68, so that the aperture ratio of the liquid crystal display device 6 is improved.

### Seventh Embodiment

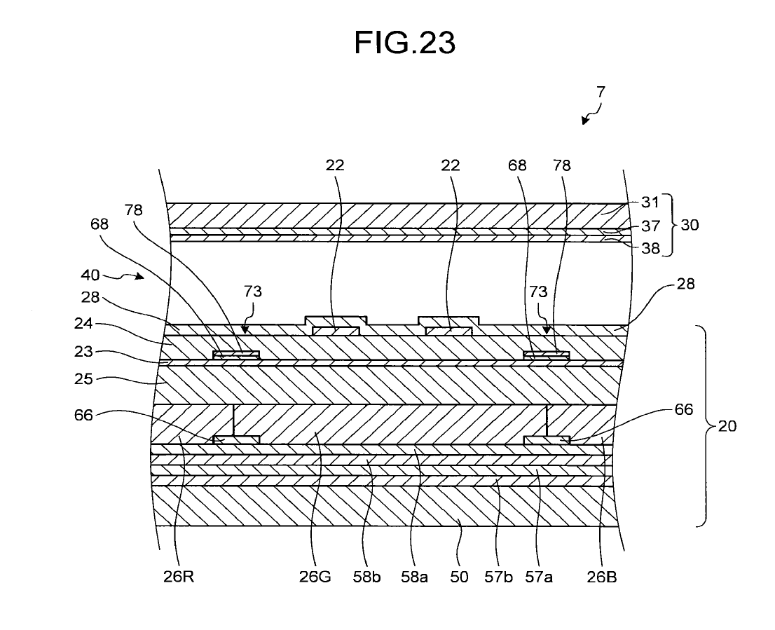

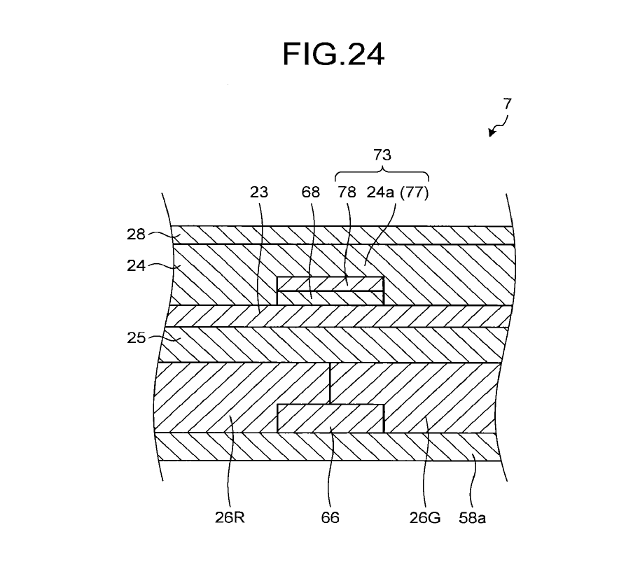

FIG. 23 is a schematic sectional view of a liquid crystal display device according to a seventh embodiment. FIG. 24 is a partial enlarged sectional view that is an enlarged view of the metal wiring and an antireflection structure. In this liquid crystal display device 7 of the present embodiment, the common electrode 23, the insulating layer 24, and the pixel electrode 22 are provided in this order on top of the overcoat layer 25. As illustrated in FIGS. 23 and 24, the liquid crystal display device 7 of the present embodiment differs from those of the fourth to sixth embodiments in that the metal wiring 68 is provided on top of the common electrode 23. The common electrode 23 has a flat plate-like shape, and is flat over locations overlapping and not overlapping the metal wiring 68. The insulating layer 24 has recessed portions on the lower surface thereof. This configuration can reduce the thickness over the metal wiring 68, and can flatten the upper surface of the insulating layer 24.

As illustrated in FIG. 24, an antireflection structure 73 is provided on top of the metal wiring 68. The antireflection structure 73 includes the light-absorbing layer 78 for reducing the reflected light from the metal wiring 68 and the optical interference layer 77 provided on top of the light-absorbing layer 78. The insulating layer 24 for insulation between layers of the pixel electrode 22 and the common electrode 23 is provided on the upper surface of the common electrode 23, the side surfaces of the metal wiring 68, and the side surfaces and the upper surface of the light-absorbing layer 78.

The film thickness of the light-absorbing layer 78 is, for example, 30 nm to 60 nm. The film thickness of the insulating layer 24 is, for example, 40 nm to 250 nm.

In the liquid crystal display device 7 of the present embodiment, providing the antireflection structure 73 on top of the metal wiring 68 restrains the reflected light from the metal wiring 68 from being viewed by the observer.

### Eighth Embodiment

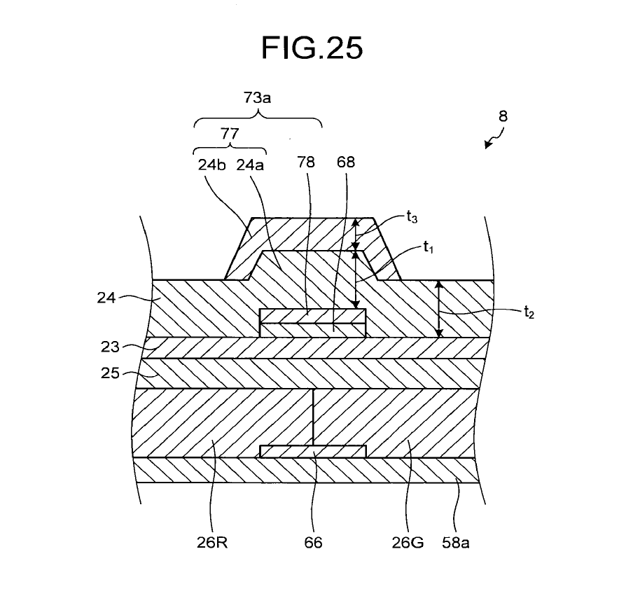

FIG. 25 is a partial enlarged sectional view that is an enlarged view of the metal wiring and an antireflection structure according to a liquid crystal display device of an eighth embodiment. In this liquid crystal display device 8 of the eighth embodiment, the insulating layer 24 projects upward at portions overlapping the metal wiring 68. The insulating layer 24 and a raised layer 24b may be different layers, or may be the same layer. If the insulating layer 24 and the raised layer 24b are the same layer, a film having a total thickness of the insulating layer 24 and the raised layer 24b is provided at a time in the production process.

In the present embodiment, the raised layer 24b is provided on top of the insulating layer 24. The raised layer 24b is provided on top of the projecting portions of the insulating layer 24, that is, above the metal wiring 68. In the present embodiment, the same material, such as silicon nitride (SiN), as that of the insulating layer 24 is used for the raised layer 24b.

As illustrated in FIG. 25, an antireflection structure 73a provided on top of the metal wiring 68 includes the light-absorbing layer 78 and the optical interference layer 77. The optical interference layer 77 includes the insulating layer 24 and the raised layer 24b provided on top of the insulating layer 24. A total film thickness (t₁+t₃) of a thickness t₁ of the insulating layer 24 (overlapping portion 24a) and a thickness t₃ of the raised layer 24b is the thickness of the optical interference layer 77.

According to the present embodiment, providing the raised layer 24b allows the thickness of the optical interference layer 77 of the antireflection structure 73a to be adjusted. Accordingly, the thickness of the optical interference layer 77 is adjusted by changing the thickness t₃ of the raised layer 24b, without changing a thickness t₂ of the insulating layer 24 provided on top of the common electrode 23. As a result, at portions of the common electrode 23 not provided with the metal wiring 68, the insulating layer 24 consisting of one layer ensures the interlayer insulation between the common electrode 23 and the pixel electrode 22, and also provides good translucency. At portions provided with the metal wiring 68, the total film thickness of the insulating layer 24 and the raised layer 24b can serve as an appropriate film thickness of the optical interference layer 77.

### Third Example

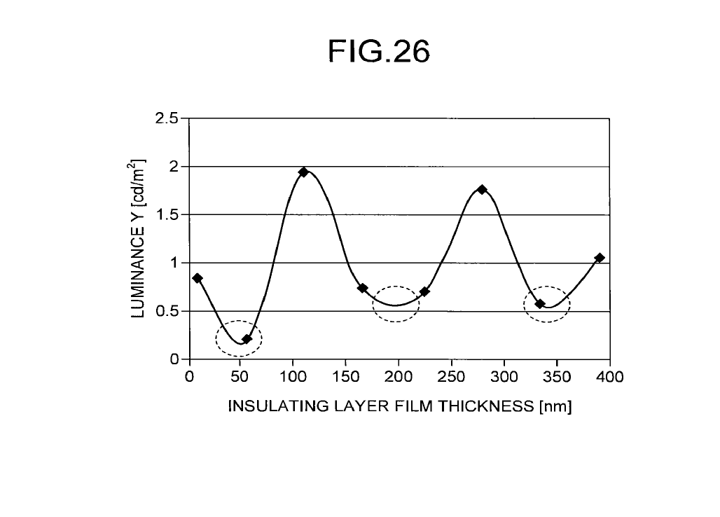

FIG. 26 is a graph illustrating a relation between the luminance Y of reflected light from metal wiring provided with an antireflection structure according to a third example and the insulating layer film thickness. The antireflection structure 73 illustrated in FIG. 24 serves as the antireflection structure according to the present example. In the present example, the film thicknesses of the light-absorbing layer 78 and the insulating layer 24 were varied, and the luminance Y and the chromaticity of the reflected light were evaluated. Then, the film thicknesses of the respective layers of the antireflection structure 73 were optimized.

The graph of FIG. 26 illustrates the relation between the film thickness of the insulating layer 24 and the luminance Y when the film thickness of the light-absorbing layer 78 is 44 nm. As illustrated in FIG. 26, the luminance Y has three local minima in the range where the film thickness of the insulating layer 24 is 10 nm to 400 nm. As indicated by the surrounding dotted lines in FIG. 26, the luminance Y exhibits three local minima at points where the film thickness of the insulating layer 24 is about 39 nm, about 175 nm, and about 330 nm. As described above, the film thickness of the insulating layer 24 is preferably in the range of, for example, 40 nm to 250 nm. In this range, the luminance Y has two local minima of a first local minimum value (near a point where the insulating layer 24 has a film thickness of 39 nm) and a second local minimum value (near a point where the insulating layer 24 has a film thickness of 175 nm).

In the present example, when manufacturing errors are taken into account, in the vicinity of the first local minimum value, the film thickness of the antireflection structure 73 for reducing the luminance Y of the reflected light is preferably such that the insulating layer 24 has a film thickness of 35 nm to 43 nm (center film thickness of 39 nm), and such that the light-absorbing layer 78 has a film thickness of 39 nm to 50 nm (center film thickness of 44 nm). In the vicinity of the second local minimum value, the film thickness of the antireflection structure 73 for reducing the luminance Y of the reflected light is preferably such that the insulating layer 24 has a film thickness of 160 nm to 190 nm (center film thickness of 175 nm), and such that the light-absorbing layer 78 has a film thickness of 39 nm to 50 nm (center film thickness of 44 nm).

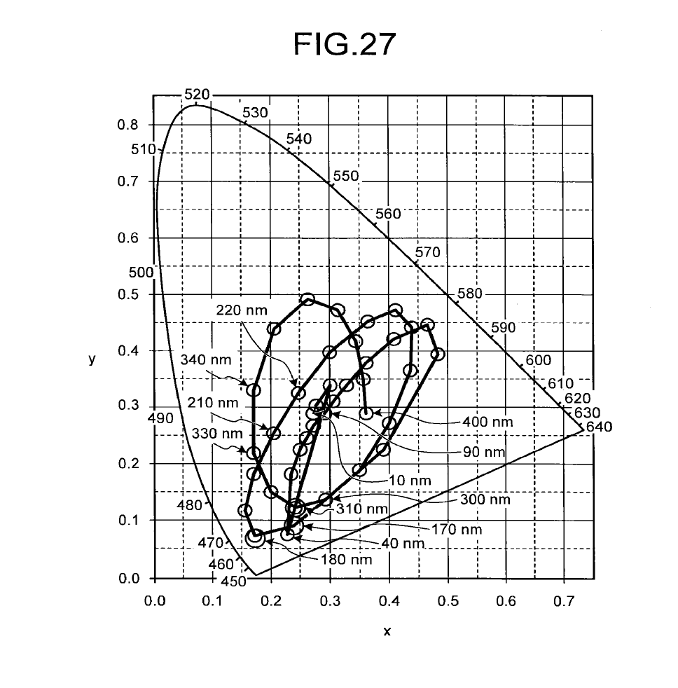

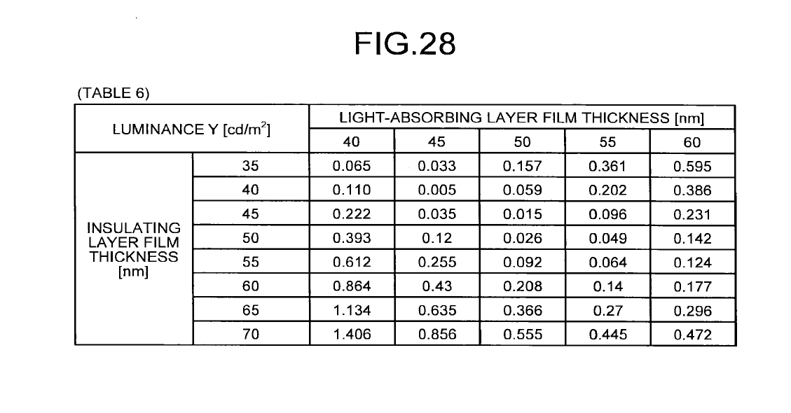

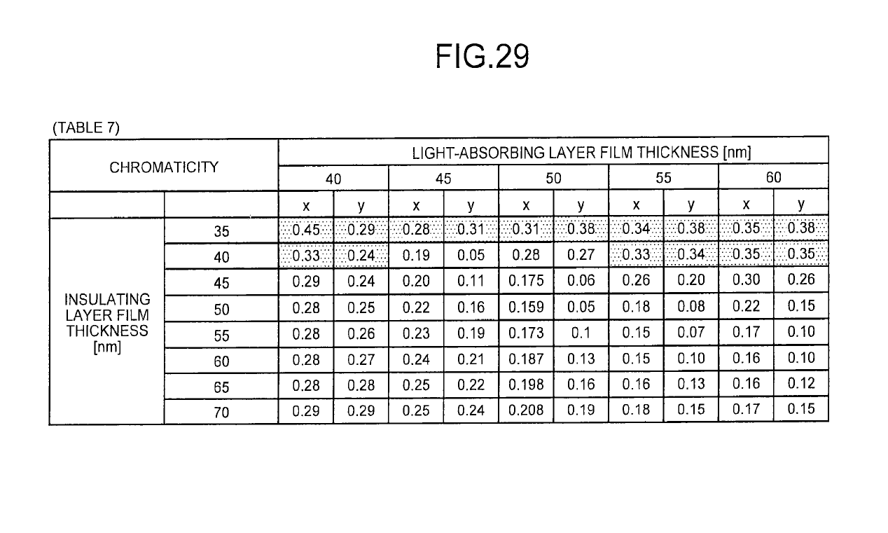

FIG. 27 is an xy chromaticity diagram based on the CIE-XYZ color system obtained by varying the thickness of the insulating layer. FIG. 28 is a table illustrating values of the luminance Y obtained by varying the insulating layer film thickness and the light-absorbing layer film thickness in the vicinity of the first local minimum value of the luminance Y. FIG. 29 is a table illustrating values of the chromaticity (x,y) obtained by varying the insulating layer film thickness and the light-absorbing layer film thickness in the vicinity of the first local minimum value of the luminance Y.

The points in FIG. 27 represent the respective chromaticities obtained by setting the film thickness of the light-absorbing layer 78 to 44 nm and the film thickness of the common electrode 23 to 100 nm, and varying the thickness of the insulating layer 24 at intervals of 10 nm in the range of 100 nm to 400 nm. The film thicknesses in the antireflection structure 73 were optimized so that the chromaticity (x,y) will satisfy x≦0.3 and y≦0.3, in addition to taking into account the luminance value Y. As illustrated in FIG. 27, the chromaticity (x,y) changes with the change in the film thickness of the insulating layer 24, and the chromaticity satisfies x≦0.3 and y≦0.3 when the film thickness of the insulating layer 24 is in the range of 32 nm to 90 nm, 167 nm to 216 nm, and 300 nm to 337 nm. When the film thickness of the insulating layer 24 is in the range of 32 nm to 90 nm, the luminance Y includes the first local minimum value, and the chromaticity satisfies x≦0.3 and y≦0.3. When the film thickness of the insulating layer 24 is in the range of 167 nm to 216 nm, the luminance Y includes the second local minimum value, and the chromaticity satisfies x≦0.3 and y≦0.3.

According to TABLE 7 of FIG. 29, the chromaticity (x,y) satisfies x≦0.3 and y≦0.3 when the film thickness of the light-absorbing layer 78 is in the range of 40 nm to 60 nm, and the film thickness of the insulating layer 24 is 45 nm or larger. As illustrated in FIGS. 26 and 28, the luminance Y tends to increase with increase in the film thickness of the insulating layer 24 when the film thickness of the insulating layer 24 is in the range of 45 nm to 70 nm. Accordingly, in the vicinity of the first local minimum value, the film thickness ranges are preferably such that the insulating layer 24 has a film thickness of 45 nm to 55 nm (center film thickness of 50 nm), and such that the light-absorbing layer 78 has a film thickness of 45 nm to 55 nm (center film thickness of 50 nm), when the luminance Y, the chromaticity (x,y), and the manufacturing errors are taken into account. The above-described film thickness range of the insulating layer 24, which is 40 nm to 250 nm, includes the film thickness range satisfying the conditions for the luminance Y and the chromaticity (x≦0.3 and y≦0.3).

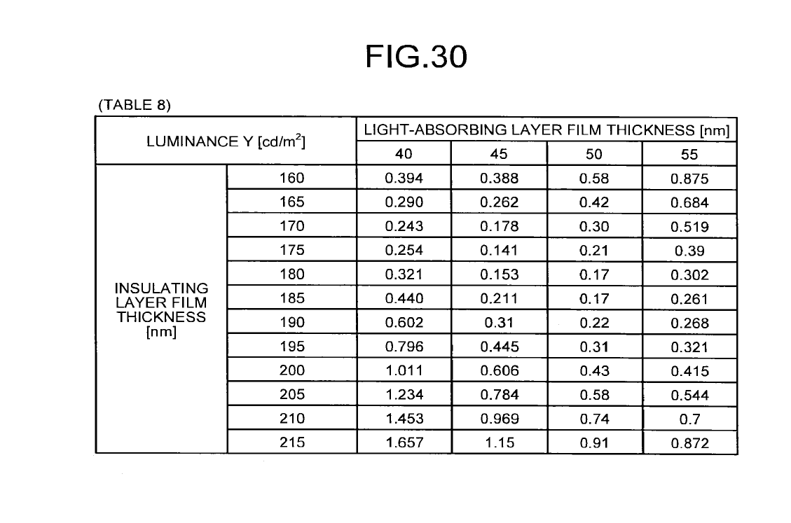

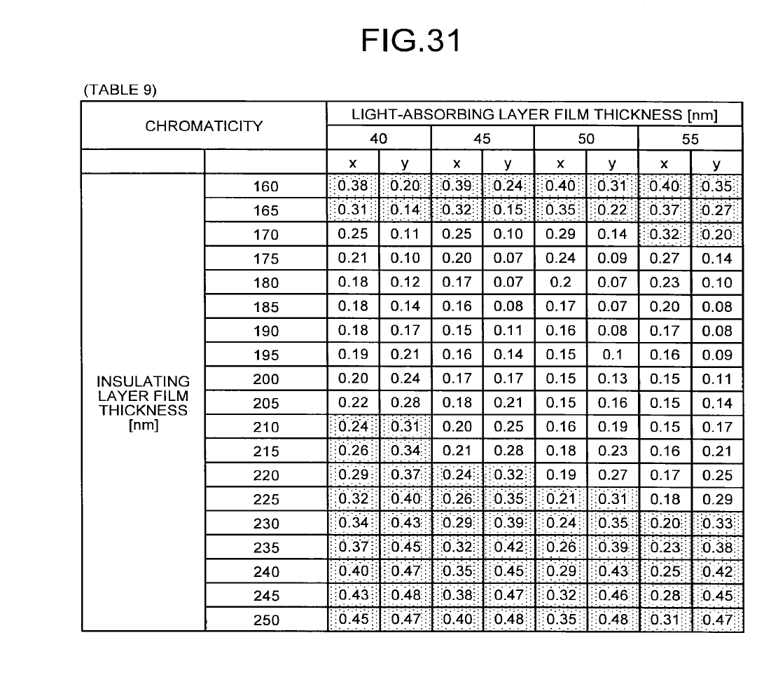

FIG. 30 is a table illustrating values of the luminance Y obtained by varying the insulating layer film thickness and the light-absorbing layer film thickness in the vicinity of the second local minimum value of the luminance Y. FIG. 31 is a table illustrating values of the chromaticity (x,y) obtained by varying the insulating layer film thickness and the light-absorbing layer film thickness in the vicinity of the second local minimum value of the luminance Y.

As illustrated in TABLE 9 of FIG. 31, the chromaticity (of x≦0.3 and y≦0.3) is satisfied when the film thickness of the light-absorbing layer 78 is in the range of 45 nm to 55 nm, and the film thickness of the insulating layer 24 is in the range of 175 nm to 215 nm. Accordingly, in the vicinity of the second local minimum value of the luminance Y, the film thickness ranges are such that the insulating layer 24 has a film thickness of 175 nm to 215 nm, (center film thickness of 195 nm), and such that the light-absorbing layer 78 has a film thickness of 45 nm to 55 nm (center film thickness of 50 nm), when the luminance Y, the chromaticity (of x≦0.3 and y≦0.3), and the manufacturing errors are taken into account. As illustrated in TABLE 8 of FIG. 30, the luminance Y is 0.141 cd/m² to 1.15 cd/m² in these ranges.

As described above, the results of the present example have indicated that the antireflection structure 73 can restrain the reflected light from the metal wiring 68 from being viewed by the observer. The results have also indicated that the luminance Y is reduced and the chromaticity (of x≦0.3 and y≦0.3) is satisfied in two film thickness regions when the film thickness of the insulating layer 24 is in the range of 40 nm to 250 nm. The two ranges of the optimal film thickness capable of preventing reflection are available. This increases the degree of design freedom, so that both the respective film thicknesses in the antireflection structure and the respective film thicknesses of the pixel electrode, the common electrode, the color filter, and the like can easily be satisfied.

While the preferred embodiments of the present invention have been described above, the present invention is not limited to such embodiments. The description disclosed in the embodiments is merely an example, and various modifications can be made without departing from the gist of the present invention. Appropriate modifications made without departing from the gist of the present invention naturally belong to the technical scope of the present invention.

For example, the liquid crystal display devices of the present embodiments include both a type in which the counter substrate includes a shielding layer and a type in which the counter substrate includes no shielding layer. The shape and the position of the shielding layer are not limited, and can be appropriately modified. For example, the common electrode may have the same shape and arrangement as those of the pixel electrode 22 described above. In this case, the pixel electrode has the same shape and arrangement as those of the common electrode 23 described above. The light-absorbing layer and the optical interference layer of the antireflection structure are not limited to those illustrated in, for example, the examples, and the material, the composition, the film thickness, and the number of layers, for example, can be modified.

Moreover, the embodiments described above can be appropriately combined. For example, the spacer 45 may be provided on top of the antireflection structure 71, 72, or 73.

What is claimed is:

1. A liquid crystal display device comprising, in sequence:
a thin-film transistor substrate comprising a thin-film transistor;
a liquid crystal layer; and
a counter substrate, wherein
the thin-film transistor substrate comprises:
a first translucent electrode;
a color filter;
metal wiring that is provided above the color filter and electrically coupled with the first translucent electrode;
a light-absorbing layer provided on the metal wiring; and
an optical interference layer provided on the light-absorbing layer, and wherein
the optical interference layer includes the first translucent electrode.

2. The liquid crystal display device according to claim 1, wherein
the thin-film transistor substrate comprises:
a second translucent electrode; and
an insulating layer interposed between the first translucent electrode and the second translucent electrode, and
the optical interference layer includes the insulating layer.

3. The liquid crystal display device according to claim 2, wherein the insulating layer is made of silicon nitride, and has a thickness of 40 nm to 250 nm.

4. The liquid crystal display device according to claim 3, wherein the insulating layer has a thickness of 61 nm to 73 nm.

5. The liquid crystal display device according to claim 3, wherein the insulating layer has a thickness of 72 nm to 88 nm, and the first translucent electrode has a thickness of 90 nm to 110 nm.

6. The liquid crystal display device according to claim 1, wherein the first translucent electrode is made of indium tin oxide, and has a thickness of 20 nm to 150 nm.

7. The liquid crystal display device according to claim 6, wherein the first translucent electrode has a thickness of 30 nm to 40 nm.

8. The liquid crystal display device according to claim 6, wherein the first translucent electrode has a thickness of 45 nm to 55 nm.

9. The liquid crystal display device according to claim 1, wherein
the thin-film transistor substrate comprises a scanning line that transmits a driving signal to the thin-film transistor and a signal line extending in a direction intersecting the scanning line, and
the light-absorbing layer is provided above the scanning line or the signal line.
